(19) United States
(12) Patent Application Publication
(10) Pub. No.: US 2017/0060303 A1
(43) Pub. Date: Mar. 2, 2017

(54) METHOD FOR MANUFACTURING TOUCH PANEL, TOUCH PANEL AND TOUCH DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Anhui (CN)

(72) Inventors: Jun CHEN, Beijing (CN); Pengyu ZHANG, Beijing (CN); Hongqiang LUO, Beijing (CN); Zhanqi XU, Beijing (CN); Xianlin DING, Beijing (CN); Taofeng XIE, Beijing (CN)

(73) Assignees: BOE TECHNOLOGY GROUP CO., LTD., Beijing (CN); HEFEI XINSHENG OPTOELECTRONICS TECHNOLOGY CO., LTD., Anhui (CN)

(21) Appl. No.: 15/227,664

(22) Filed: Aug. 3, 2016

(30) Foreign Application Priority Data
Aug. 24, 2015 (CN) 201510523259.9

(51) Int. Cl. G06F 3/044; H05K 1/09; H05K 3/06; H05K 1/02

(52) U.S. Cl. CPC G06F 3/044; H05K 1/0296; H05K 1/09; H05K 3/064; G06F 2203/04111; G06F 2203/04103; H05K 2201/032

(57) ABSTRACT

Disclosed are a method for manufacturing a touch panel, a touch panel and a touch display device. The method includes: forming signal lines and multiple connection bridges disposed in a matrix on a substrate; forming multiple isolation films on the substrate provided with the signal lines and the multiple connection bridges, where the multiple isolation films are in one-to-one correspondence with the multiple connection bridges and each isolation film covers a portion of one corresponding connection bridge; and forming multiple first touch electrodes and multiple second touch electrodes made of nano-silver on the substrate provided with the multiple isolation films. The first touch electrodes and the second touch electrodes are connected to the signal lines. Each first touch electrode includes multiple first sub-electrodes. Adjacent first sub-electrodes are bridged through corresponding connection bridges. The second touch electrodes are insulated from the connection bridges through the isolation films.

### CROSS-REFERENCE TO RELATED APPLICATION

The present application claims a priority to Chinese Patent Application No. 201510523259.9 filed on Aug. 24, 2015, the disclosure of which is incorporated in its entirety by reference herein.

### TECHNICAL FIELD

The present disclosure relates to the field of touch screen, and in particular to a method for manufacturing a touch panel, a touch panel and a touch display device.

### BACKGROUND

In related technologies, touch electrodes of a touch panel are made of indium tin oxid (ITO, a kind of conductive glass). Depositing an ITO pattern layer requires a film-plating process, which is expensive. The ITO pattern layer is prone to generate breakages and the depositing requires good film-plating quality and good flatness of a substrate; accordingly, the touch electrodes made of ITO are not suitable for a large touch product.

### SUMMARY

The present disclosure provides a method for manufacturing a touch panel, a touch panel and a touch display device, with which touch electrodes are made of nano-silver; thus, the equipment cost is reduced and the quality of the touch panel is improved.

It is provided a method for manufacturing a touch panel in the present disclosure, and the method includes:
forming signal lines and multiple connection bridges on a substrate, the multiple connection bridges being disposed in the form of a matrix;
forming multiple isolation films on the substrate provided with the signal lines and the multiple connection bridges, where multiple isolation films are in one-to-one correspondence with the multiple connection bridges and each isolation film covers a portion of one corresponding connection bridge;
forming multiple first touch electrodes and multiple second touch electrodes, which are made of nano-silver, on the substrate provided with the multiple isolation films, where the multiple first touch electrodes and the multiple second touch electrodes are connected to the signal lines;
where each of the multiple first touch electrodes comprises multiple first sub-electrodes, any two adjacent first sub-electrodes among the multiple first sub-electrodes are bridged through one corresponding connection bridge, and the multiple second touch electrodes are insulated from the multiple connection bridges through the multiple isolation films.

Optionally, the step of forming the multiple first touch electrodes and the multiple second touch electrodes, which are made of nano-silver, on the substrate provided with the multiple isolation films may include:
depositing, through a coating process, a layer of nano-silver glue on the substrate provided with the multiple isolation films; and
curing the nano-silver glue to form a nano-silver layer.

Optionally, the step of forming the multiple first touch electrodes and the multiple second touch electrodes, which are made of nano-silver, on the substrate provided with the multiple isolation films may further include:
coating a first photoresist on the nano-silver layer;
forming a first photoresist reserved region and a first photoresist unreserved region through performing exposure using a mask plate and development on the first photoresist, where the first photoresist reserved region corresponds to a region where the multiple first touch electrodes and the multiple second touch electrodes are located, and the first photoresist unreserved region corresponds to the other region;
etching the nano-silver layer in the first photoresist unreserved region and forming patterns of the first touch electrodes and the second touch electrodes made of nano-silver; and
reserving the remaining first photoresist.

Optionally, before the step of forming the signal lines and the multiple connection bridges, the method may further include: forming a black frame on the substrate, where the black border is a frame surrounding a display region of the touch panel. The signal lines overlap the black frame in a light-transmitting direction of the display region, and the multiple connection bridges are surrounded by the black frame.

Optionally, the step of forming the multiple isolation films on the substrate provided with the signal lines and the multiple connection bridges may include:
forming an insulating black frame material layer on the substrate provided with the signal lines and the multiple connection bridges;
coating a second photoresist on the black frame material layer;
forming a second photoresist fully-reserved region and a second photoresist unreserved region through performing exposure using a mask plate and development on the second photoresist, where the second photoresist fully-reserved region corresponds to a region where patterns of a black frame and the isolation films are located, the second photoresist unreserved region corresponds to the other region, and the black frame is a frame surrounding a display region of the touch panel;
etching the black frame material layer of the second photoresist unreserved region and forming the patterns of the black frame and the isolation films made of a black frame material; where the signal lines overlap the black frame in a light-transmitting direction of the display region, and the multiple connection bridges are surrounded by the black frame; and
removing the remaining second photoresist.

Optionally, a patterning process for the multiple isolation films may include:
depositing a transparent insulating material layer and a black frame material layer in sequence on the substrate provided with the signal lines and the multiple connection bridges;
coating a third photoresist on the black frame material layer;
forming a third photoresist fully-reserved region, a third photoresist partially-reserved region and a third photoresist unreserved region through performing exposure using a halftone mask plate and development on the third photoresist; where the third photoresist fully-reserved region corresponds to a region where a pattern of a black frame is located, the third photoresist partially-reserved region corresponds to a region where patterns of the isolation films are located, and the third photoresist unreserved region corresponds to the other region, and the black frame is a frame surrounding a display region of the touch panel;
etching the black frame material layer and the transparent insulating material layer in the third photoresist unreserved region;
ashing the third photoresist in the third photoresist partially-reserved region;
etching the black frame material layer in the third photoresist partially-reserved region and forming the patterns of the isolation films which are only generated from the transparent insulating material layer; where the signal lines overlap the black frame in a light-transmitting direction of the display region, and the multiple connection bridges are surrounded by the black frame; and
removing the remaining third photoresist.

Optionally, each isolation film covers a middle portion of one corresponding connection bridge.

Optionally, each connection bridge extends along a column direction, the multiple first sub-electrodes of each first touch electrode extend along the column direction and are bridged through a corresponding column of connection bridges; each isolation film extends along a row direction, each second touch electrode extends along the row direction and comprises multiple second sub-electrodes, connecting portions between adjacent second sub-electrodes are located on a corresponding row of isolation films.

Optionally, the number of columns of the multiple connection bridges is equal to the number of the multiple first touch electrodes, the number of rows of the multiple connection bridges is less than the number of the first sub-electrodes of each first touch electrode by 1; and the number of rows of the multiple isolation films is equal to the number of the multiple second touch electrodes, and the number of columns of the multiple isolation films is less than the number of the second sub-electrodes of each second touch electrode by 1.

It is further provided a touch panel in the present disclosure, which includes:
a substrate;
signal lines and multiple connection bridges formed on the substrate, the multiple connection bridges being disposed in the form of a matrix;
multiple isolation films in one-to-one correspondence with the multiple connection bridges, where each isolation film covers at least a portion of one corresponding connection bridge; and
multiple first touch electrodes and multiple second touch electrodes which are made of nano-silver; where the multiple first touch electrodes and the multiple second touch electrodes are connected to the signal lines, each of the multiple first touch electrodes comprises multiple first sub-electrodes, any two adjacent first sub-electrodes among the multiple first sub-electrodes are bridged through one corresponding connection bridge, and the multiple second touch electrodes are insulated from the multiple connection bridges through the multiple isolation films.

Optionally, the touch panel may further include: a black frame, where the black frame is a frame surrounding a display region of the touch panel, and the black frame is disposed between the substrate and the signal lines or disposed at an identical layer to the multiple isolation films. The signal lines at least partially overlap the black frame.

Optionally, in the above touch panel, each isolation film covers a middle portion of one corresponding connection bridge.

Optionally, in the above touch panel, each connection bridge extends along a column direction, the multiple first sub-electrodes of each first touch electrode extend along the column direction and are bridged through a corresponding column of connection bridges; each isolation film extends along a row direction, each second touch electrode extends along the row direction and comprises multiple second sub-electrodes, connecting portions between adjacent second sub-electrodes are located on a corresponding row of isolation films.

Optionally, in the above touch panel, the number of columns of the multiple connection bridges is equal to the number of the multiple first touch electrodes, the number of rows of the multiple connection bridges is less than the number of the first sub-electrodes of each first touch electrode by 1; and the number of rows of the multiple isolation films is equal to the number of the multiple second touch electrodes, and the number of columns of the multiple isolation films is less than the number of the second sub-electrodes of each second touch electrode by 1.

Furthermore, it is further provided a touch display device including any one of the touch panels described above.

In the technical solutions of the present disclosure, the touch electrodes are made of the organic nano-silver, compared with manufacturing touch electrodes using ITO, the demand of the flatness of the substrate is less critical during manufacturing the touch electrodes in the present disclosure; therefore, the manufacturing method of the present disclosure is especially suitable to product a large touch screen, and the problem that ITO technology cannot be utilized in manufacturing large products is solved.

### BRIEF DESCRIPTION OF THE DRAWINGS

FIG. 1A to FIG. 1D are schematic views of a method for manufacturing a touch panel according to some embodiments of the present disclosure;

FIG. 1D1 to FIG. 1D4 are detailed schematic views of FIG. 1D;

FIG. 2A to FIG. 2C are schematic views of a method for manufacturing a touch panel according to some embodiments of the present disclosure;

FIG. 2B1 to FIG. 2B4 are detailed schematic views of FIG. 2B;

FIG. 3A to FIG. 3C are schematic views of a method for manufacturing a touch panel according to some embodiments of the present disclosure;

FIG. 3B1 to FIG. 3B6 are detailed schematic views of FIG. 3B; and

FIG. 4 is a schematic structural diagram of a touch panel according to some embodiments of the present disclosure.

### REFERENCE NUMERALS

1:substrate; 2:black frame; 31:signal lines; 32:connection bridges;
41:isolation films; 42:signal line protection film;
51:first touch electrodes; 52:second touch electrodes.

### DETAILED DESCRIPTION OF THE EMBODIMENTS

In order to make the technical solutions and the advantages of the present disclosure more apparent, the present disclosure will be described hereinafter in detail in conjunction with the drawings and specific embodiments.

In view of problems of the related technologies, it is provided a method for manufacturing a touch panel in the present disclosure, which includes following steps.

Signal lines and connection bridges are formed on a substrate. The signal lines and the connection bridges are made of a conductive material. The signal lines are connected to touch electrodes manufactured later and are for transmitting signals on the touch electrodes. The touch panel includes multiple first touch electrodes and multiple second touch electrodes intersecting with the multiple first touch electrodes. The connection bridges are located at intersections between the first touch electrodes and the second touch electrodes, such that the first touch electrodes and the second touch electrodes are spaced in a direction perpendicular to the touch panel.

Isolation films are formed on the substrate provided with the signal lines and the connection bridges, where each isolation film covers a portion of one corresponding connection bridge. The first touch electrodes are not in contact with the second touch electrodes due to the isolation films on the connection bridges; thus, the first touch electrodes are insulated from the second touch electrodes.

The multiple first touch electrodes and the multiple second touch electrodes made of nano-silver are formed on the substrate provided with the isolation films. The first touch electrodes and the second touch electrodes are connected to the signal line. Each first touch electrode includes multiple first sub-electrodes, and adjacent first sub-electrodes are bridged through the connection bridges. The second touch electrodes are insulated from the connection bridges through the isolation films.

Compared with using ITO to manufacture the touch electrodes in the related technologies, the demand of the flatness of the substrate is less critical during manufacturing the touch electrodes with nano-silver, which is an organic material, according to embodiments of the present disclosure, it is easy to form a meandering pattern with nano-silver on the substrate, and the method of the present disclosure is especially suitable to product a large touch screen; thus solving the problem that the ITO technology cannot be utilized in manufacturing large products. Furthermore, a nano-silver conductive solution is an organic material, the touch electrodes can be manufactured using a coating process, compared to the film-plating process, equipment investment is smaller and such method in the present disclosure has a great promotion value.

A method for manufacturing a touch panel provided in the present disclosure will be described in detail hereinafter in conjunction with embodiments of the present disclosure.

It is provided a method for manufacturing a touch panel according to some embodiments of the present disclosure, which includes the following steps 11 to 14.

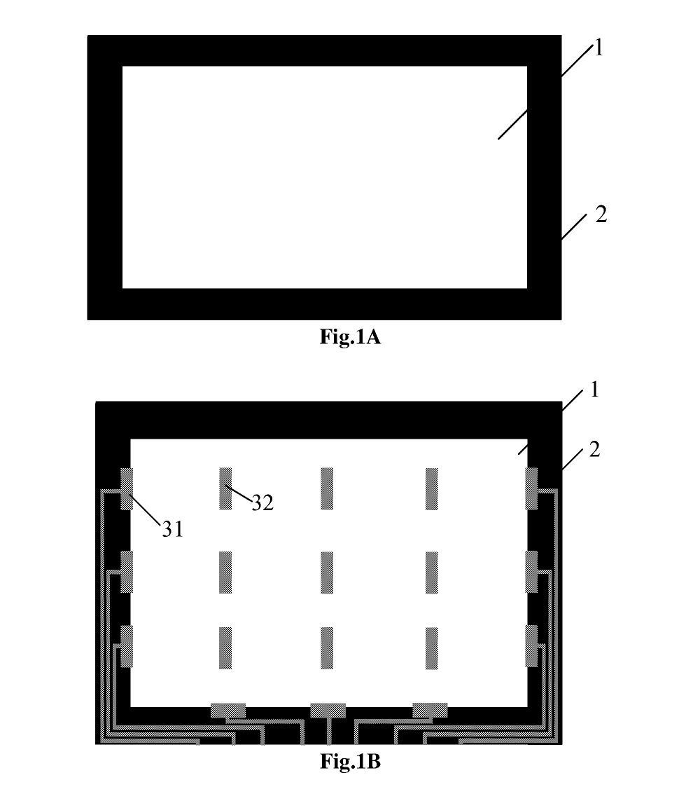

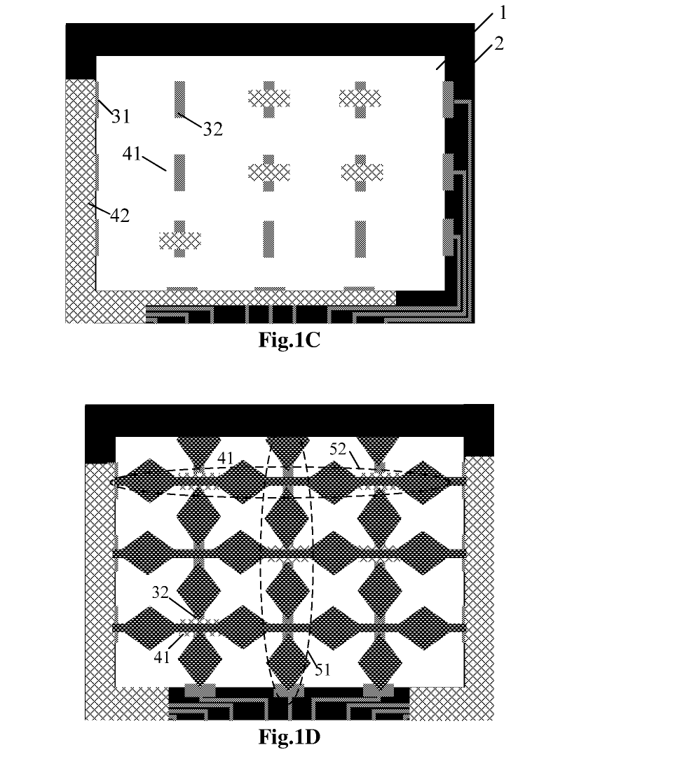

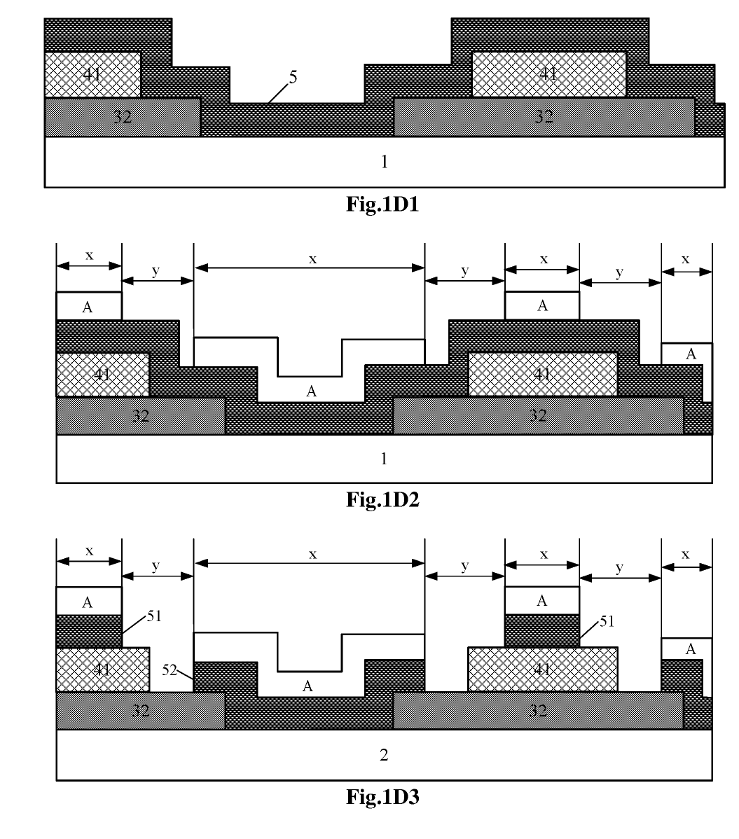

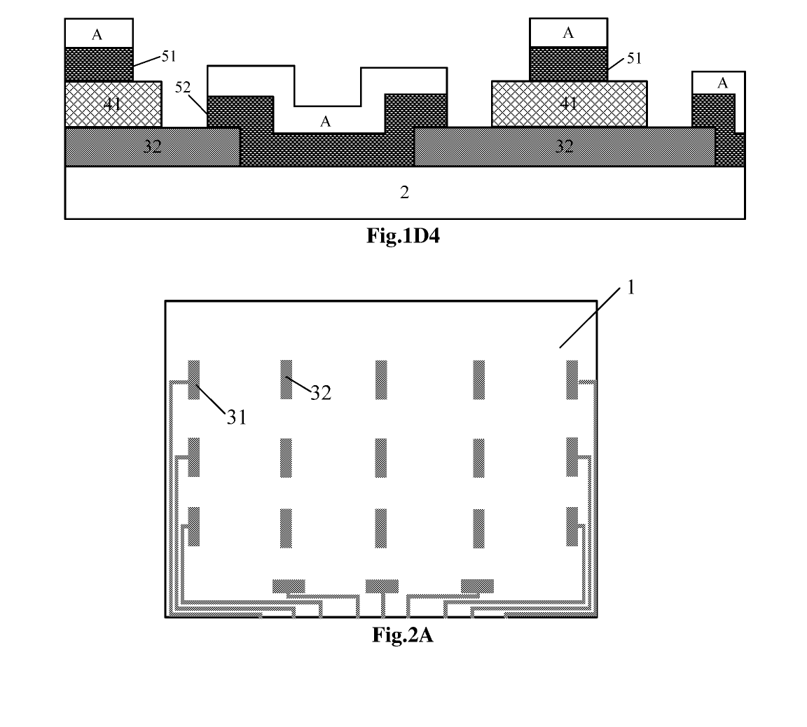

In step 11, as shown in FIG. 1A, a black frame 2 is formed on a substrate 1 through one patterning process. The black frame 2 is a frame surrounding a display region of the touch panel.

In step 12, as shown in FIG. 1B, signal lines 31 and multiple connection bridges 32 are formed on the substrate 1 through one patterning process. The multiple connection bridges 32 are disposed in the form of a matrix.

In order not to affect light transmission of the display region, the signal lines 31 at least partially overlap the black frame 2 in a light-transmitting direction of the display region.

In step 13, as shown in FIG. 1C, multiple isolation films 41 and a signal line protection layer 42 made of an insulating material are further formed on the substrate through one patterning process.

The multiple isolation films 41 is arranged in one-to-one correspondence with the multiple connection bridges 32, and each isolation film 41 covers a middle portion of a corresponding connection bridge 32. The second touch electrodes manufactured later locate on the isolation films 41. It should be noted that, the signal line protection layer 42 is not an essential functional pattern and the arrangement thereof is only optional.

In step 14, as shown in FIG. 1D, multiple first touch electrodes 51 and multiple second touch electrodes 52 made of nano-silver are formed through one patterning process on the substrate provided with the multiple isolation film 41 and the signal line protection layer 42.

Each first touch electrode 51 and each second touch electrode 52 include multiple sub-electrodes (i.e., rhombuses in FIG. 1D). The sub-electrodes of each first touch electrode 51 are separated from each other and electric connection between the sub-electrodes of the first touch electrode 51 is implemented via a column of connection bridges 32. The multiple sub-electrodes of the second touch electrode 52 are integrally formed during a manufacture procedure and connecting portions between the sub-electrodes of the second touch electrode 52 are located on a row of isolation films 41, thereby insulating the second touch electrode 52 from the first touch electrodes 51.

Specifically, a procedure for manufacturing the first touch electrodes 51 and the second touch electrodes 52 includes the following steps 141 to 144.

In step 141, as shown in FIG. 1D1, a layer of nano-silver glue is deposited on the substrate provided with the connection bridges 32 and the isolation films 41 by means of a coating process, and the nano-silver glue is dried and cured to form a nano-silver layer 5.

In step 142, as shown in FIG. 1D2, a first photoresist A is coated on the nano-silver layer, and a first photoresist reserved region x and a first photoresist unreserved region y are formed through performing exposure using a mask plate and development on the first photoresist A. The first photoresist reserved region x is a region covered by the first photoresist A and corresponds to patterns of the first touch electrodes and the second touch electrodes, and the first photoresist unreserved region y is the other region not covered by the first photoresist A.

In step 143, as shown in FIG. 1D3, the nano-silver layer in the first photoresist unreserved region is etched so as to form patterns of the first touch electrode 51 and the second touch electrode 52 made of nano-silver.

In step 144, as shown in FIG. 1D4, the remaining first photoresist A is reserved. In this step, since the patterns of the first touch electrode 51 and the second touch electrode 52 are formed in the last step of the manufacturing method, the first photoresist A covering the first touch electrodes 51 and the second touch electrodes 52 needs not to be removed, and the remaining first photoresist A can further protect the first touch electrodes 51 and the second touch electrodes 52.

As can be seen, the above manufacturing method has four patterning processes respectively for forming the black frame, the connection bridges and the signal lines, the isolation films, and the first touch electrodes and the second touch electrodes.

It is further provided a method for manufacturing a touch panel according to some embodiments of the present disclosure, which includes three pattering processes and includes the following steps 21 to 23.

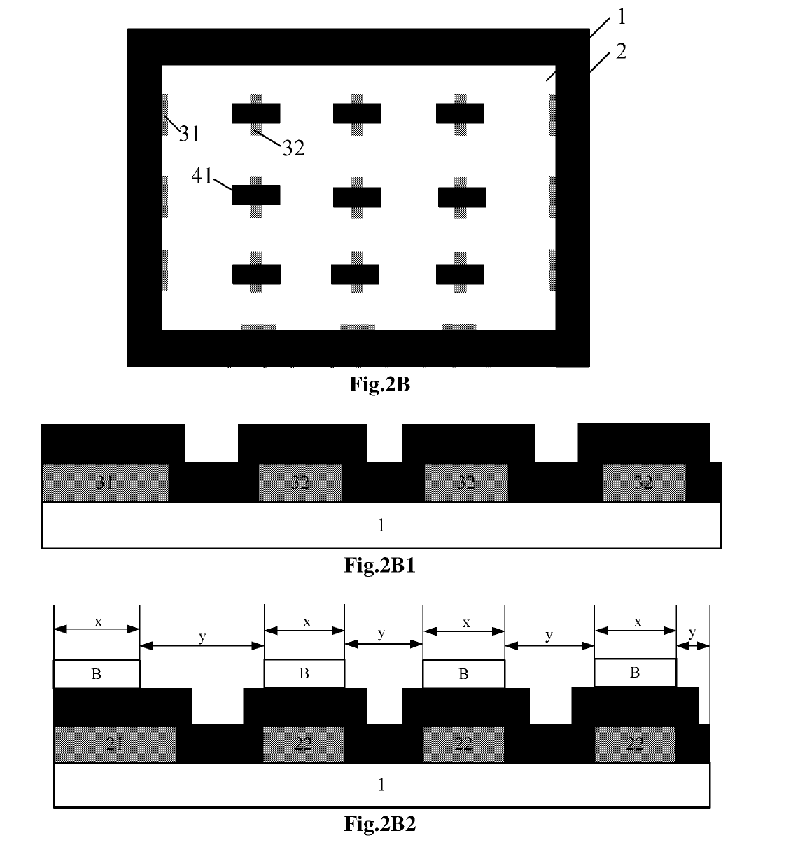

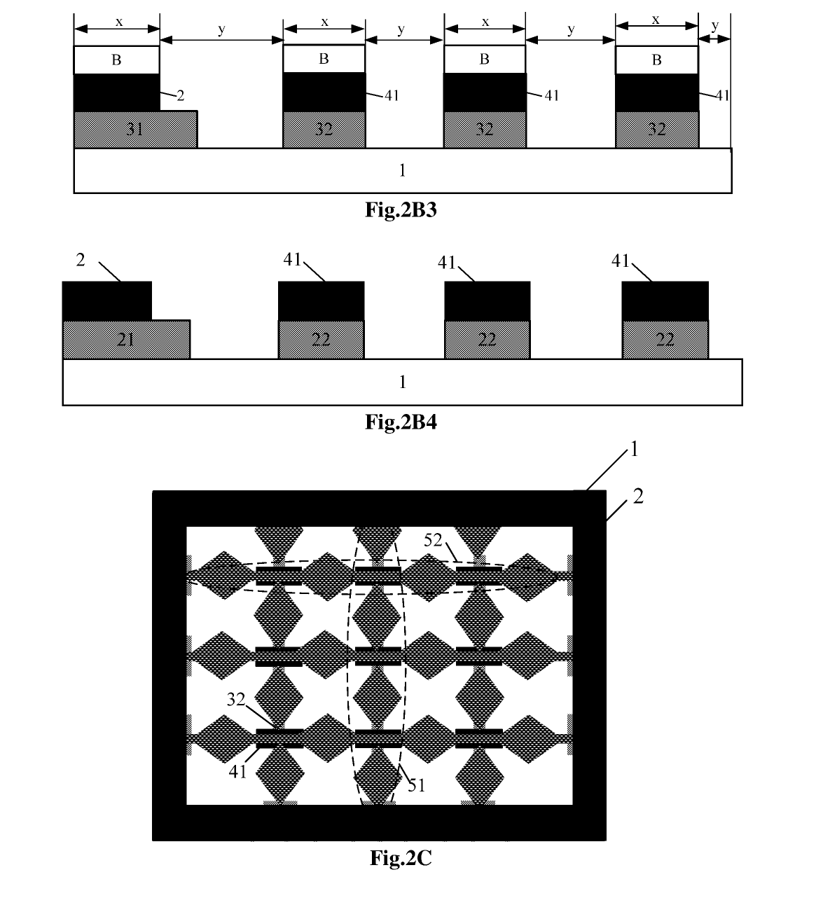

In step 21, as shown in FIG. 2A, signal lines 31 and connection bridges 32 made of a conductive material are formed on a substrate 1 through one patterning process.

In step 22, as shown in FIG. 2B, a black frame 2 and isolation films 41 are formed through one patterning process on the substrate 1 provided with the signal lines 31 and the connection bridges 32.

In this step, since there is no functional conflict between the black frame 2 and the isolation films 41, the black frame 2 and the isolation films 41 may be made of a same material layer. Specifically, the step 22 includes steps 221 to 224.

In step 221, as shown in FIG. 2B 1, an insulating black frame material layer (i.e., a black pattern layer shown in FIG. 2B1) is deposited on the substrate 1 provided with the signal lines 31 and the connection bridges 32.

In step 222, as shown in FIG. 2B2, a second photoresist B is coated on the black frame material layer, and a second photoresist fully-reserved region x and a second photoresist unreserved region y are formed through performing exposure using a mask plate and development on the second photoresist B. The second photoresist fully-reserved region x is a region covered by the second photoresist B and corresponds to patterns of the black frame and the isolation films, and the second photoresist unreserved region y is the other region not covered by the second photoresist B.

In step 223, as shown in FIG. 2B3, the black frame material layer in the second photoresist unreserved region y is etched so as to form patterns of the black frame 2 and the isolation films 41 made of a black frame material. The black frame 2 covers a portion of each signal line 31.

In step 224, as shown in FIG. 2B4, the remaining second photoresist B is removed.

Step 23 is performed after the black frame 2 and the isolation films 41 are manufactured. As shown in FIG. 2C, multiple first touch electrodes 51 and multiple second touch electrodes 52 made of nano-silver are further formed on the substrate 1 through one patterning process. This step is same as the step for forming the touch electrodes in the manufacturing method according to the foregoing embodiments, which will not be repeated here.

In the manufacturing method, the black frame and the isolation films are formed in one patterning process; thus, manufacturing cost of the touch panel is reduced effectively.

It is further provided a method for manufacturing a touch panel according to some embodiments of the present disclosure, which has three patterning processes and includes the following steps 31 to 33.

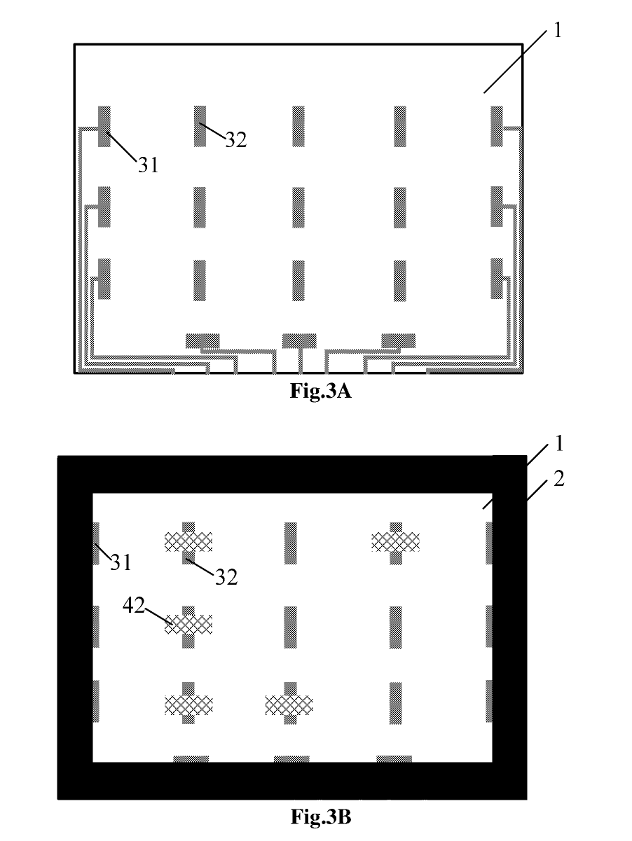

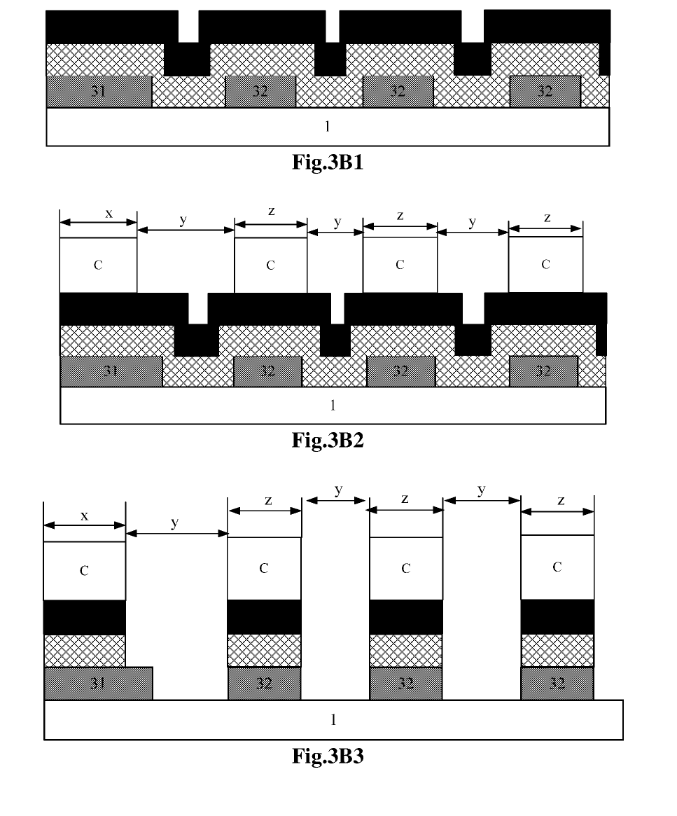

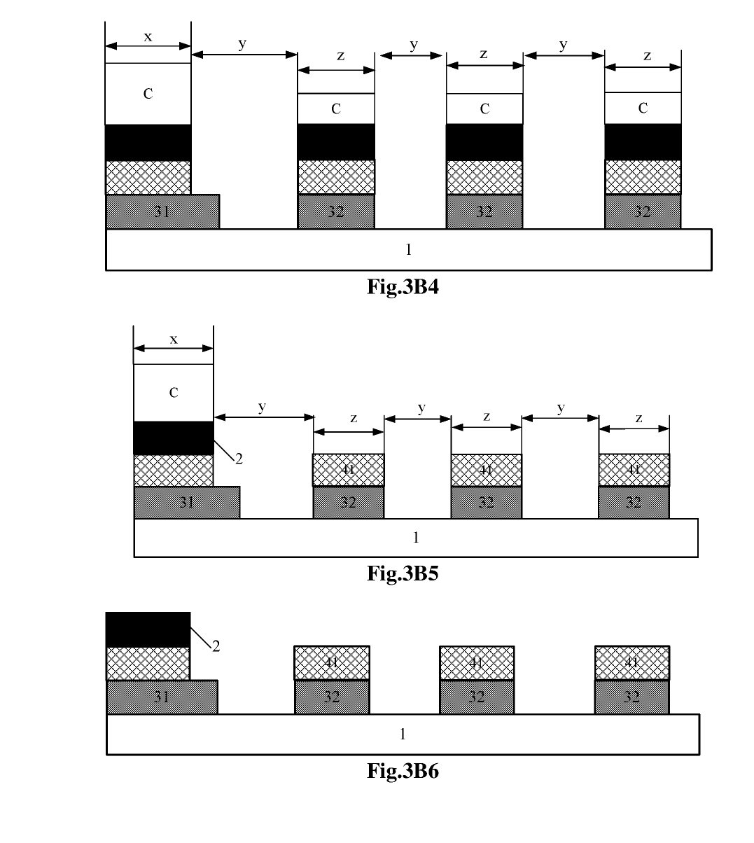

In step 31, as shown in FIG. 3A, signal lines 31 and connection bridges 32 made of a conductive material are formed on a substrate 1 through one patterning process.

In step 32, as shown in FIG. 3B, a black frame 2 and isolation films 41 are formed on the substrate 1 through one patterning process.

In this step, the black frame 2 and the isolation films 41 are made of different materials. Specifically, the step 32 may include the following steps 321 to 326.

In step 321, as shown in FIG. 3B 1, a transparent insulating material layer (i.e., a grid-like pattern layer shown in FIG. 3B1) and a black frame material layer (i.e., a black pattern layer shown in FIG. 3B1) are deposited in sequence on the substrate 1 provided with the signal lines 31 and the connection bridges 32.

In step 322, as shown in FIG. 3B2, a third photoresist C is coated on the black frame material layer, and a third photoresist fully-reserved region x, a third photoresist partially-reserved region z and a third photoresist unreserved region y are formed through performing exposure using a halftone mask plate and development on the third photoresist C. The third photoresist fully-reserved region x corresponds to a region where a pattern of the black frame is located, the third photoresist partially-reserved region z corresponds to a region where patterns of the isolation films are located, and the third photoresist unreserved region y corresponds to the other region.

In step 323, as shown in FIG. 3B3, the black frame material layer and the transparent insulating material layer in the third photoresist unreserved region y are etched.

In step 324, as shown in FIG. 3B4, the third photoresist C in the third photoresist partially-reserved region z is ashed and the thickness of the third photoresist C in the third photoresist partially-reserved region z is reduced to approximate half of an original thickness thereof.

In step 325, as shown in FIG. 3B5, the black frame material layer in the third photoresist partially-reserved region z is etched to form patterns of the isolation films 41 which are only generated from the transparent insulating material layer.

In step 326, the remaining third photoresist C is removed.

Step 23 is performed after the black frame 2 and the isolation films 41 are formed. As shown in FIG. 3C, multiple first touch electrodes 51 and multiple second touch electrodes 52 made of nano-silver are further formed on the substrate 1 through one patterning process. This step is same as the step for forming the touch electrodes in the manufacturing method according to foregoing embodiments, which will not be repeated here.

In the above manufacturing method, the black frame and the isolation films are formed in one patterning process and the isolation films formed in the display region are transparent; therefore, light transmission of a display device including the touch panel is assured.

In summary, in the manufacturing methods provided in the present disclosure, the touch electrodes are made of nano-silver; compared with manufacturing the touch electrodes using ITO, the demand of the flatness of the substrate in the manufacturing methods of the present disclosure is less critical; therefore, the manufacturing methods of the present disclosure are especially suitable to product a large touch screen.

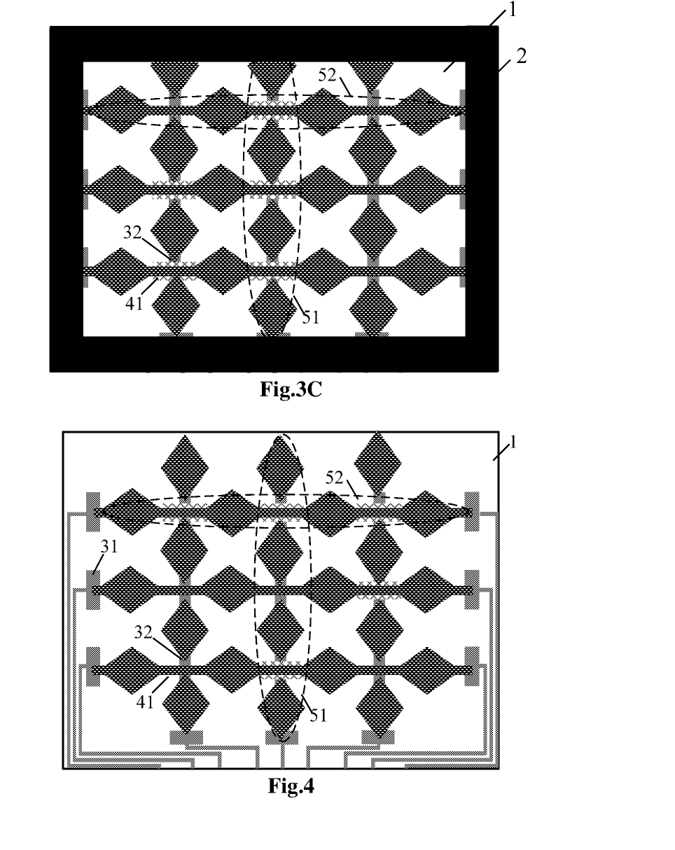

Moreover, corresponding to the above manufacturing methods, it is further provided a touch panel according to some embodiments of the present disclosure. As shown in FIG. 4, the touch panel includes: a substrate 1; signal lines 31 and multiple connection bridges 32 forming on the substrate 1, where the multiple connection bridges 32 are disposed in the form of a matrix; multiple isolation films 41 arranged in a one-to-one correspondence with the multiple connection bridges 32, where each isolation film 41 at least covers a portion of a corresponding connection bridge 32; and multiple first touch electrodes 51 and multiple second touch electrodes 52 made of nano-silver, which are connected to the signal lines 31, where each first touch electrode 51 includes multiple first sub-electrodes (i.e., rhombuses in FIG. 4), the multiple first sub-electrodes are bridged through a corresponding column of connection bridges 32, and the multiple second touch electrodes are insulated from the multiple connection bridges 32 through the multiple isolation films 41.

It should be noted that, the touch panel in the embodiments is manufactured using the manufacturing methods of the present disclosure and is in accordance with any of the above manufacturing methods. Therefore, it can be known that as shown in FIG. 1D, FIG. 2C and FIG. 3C, the touch panel may further include a black frame 2 partially overlapping each of the signal lines 31. The black frame 2 may be disposed between the substrate 1 and the signal lines 31, or may be alternatively disposed at an identical layer to the isolation films 41 and even made of an identical material to the isolation films 41.

Furthermore, it is provided a touch display device including the above touch panel according to some embodiments of the present disclosure. The touch display device may be a mobile phone, a PAD, a vehicle-mounted terminal or the like. In particular, with respect to a display device including a large touch panel, the entire touch electrode layer made of nano-silver may hardly generate breakages and can provide better user experience in touch recognition.

Those described above are preferred embodiments of the present disclosure. It should be noted that, the skilled in the art can make improvements and modifications without departing from the principle of the disclosure, and those improvements and modifications all fall in the scope of protection of the present disclosure.

What is claimed is:

1. A method for manufacturing a touch panel, comprising:
forming signal lines and a plurality of connection bridges on a substrate, the plurality of connection bridges being disposed in the form of a matrix;
forming a plurality of isolation films on the substrate provided with the signal lines and the plurality of connection bridges, wherein the plurality of isolation films is arranged in one-to-one correspondence with the plurality of connection bridges and each isolation film covers a portion of one corresponding connection bridge;
forming a plurality of first touch electrodes and a plurality of second touch electrodes, which are made of nano-silver, on the substrate provided with the plurality of isolation films, wherein the plurality of first touch electrodes and the plurality of second touch electrodes are connected to the signal lines;
wherein each of the plurality of first touch electrodes comprises a plurality of first sub-electrodes, any two adjacent first sub-electrodes among the plurality of first sub-electrodes are bridged through one corresponding connection bridge, and the plurality of second touch electrodes is insulated from the plurality of connection bridges through the plurality of isolation films.

2. The method according to claim 1, wherein the step of forming the plurality of first touch electrodes and the plurality of second touch electrodes, which are made of nano-silver, on the substrate provided with the plurality of isolation films comprises:
depositing, through a coating process, a layer of nano-silver glue on the substrate provided with the plurality of isolation films; and
curing the nano-silver glue to form a nano-silver layer.

3. The method according to claim 2, wherein the step of forming the plurality of first touch electrodes and the plurality of second touch electrodes, which are made of nano-silver, on the substrate provided with the plurality of isolation films further comprises:
coating a first photoresist on the nano-silver layer;
forming a first photoresist reserved region and a first photoresist unreserved region through performing exposure using a mask plate and development on the first photoresist, wherein the first photoresist reserved region corresponds to a region where the plurality of first touch electrodes and the plurality of second touch electrodes are located, and the first photoresist unreserved region corresponds to the other region;
etching the nano-silver layer in the first photoresist unreserved region and forming patterns of the first touch electrodes and the second touch electrodes made of nano-silver; and
reserving the remaining first photoresist.

4. The method according to claim 1, wherein before the step of forming the signal lines and the plurality of connection bridges, the method further comprises:
forming a black frame on the substrate, wherein the black frame is a frame surrounding a display region of the touch panel;
wherein the signal lines overlap the black frame in a light-transmitting direction of the display region, and the plurality of connection bridges are surrounded by the black frame.

5. The method according to claim 1, wherein the step of forming the plurality of isolation films on the substrate provided with the signal lines and the plurality of connection bridges comprises:
forming an insulating black frame material layer on the substrate provided with the signal lines and the plurality of connection bridges;
coating a second photoresist on the black frame material layer;
forming a second photoresist fully-reserved region and a second photoresist unreserved region through performing exposure using a mask plate and development on the second photoresist, wherein the second photoresist fully-reserved region corresponds to a region where patterns of a black frame and the isolation films are located, the second photoresist unreserved region corresponds to the other region, and the black frame is a frame surrounding a display region of the touch panel;
etching the black frame material layer of the second photoresist unreserved region and forming the patterns of the black frame and the isolation films made of the black frame material; wherein the signal lines overlap the black frame in a light-transmitting direction of the display region, and the plurality of connection bridges are surrounded by the black frame; and
removing the remaining second photoresist.

6. The method according to claim 1, wherein a patterning process for the plurality of isolation films comprises:
depositing a transparent insulating material layer and a black frame material layer in sequence on the substrate provided with the signal lines and the plurality of connection bridges;
coating a third photoresist on the black frame material layer;
forming a third photoresist fully-reserved region, a third photoresist partially-reserved region and a third photoresist unreserved region through performing exposure using a halftone mask plate and development on the third photoresist; wherein the third photoresist fully-reserved region corresponds to a region where a pattern of a black frame is located, the third photoresist partially-reserved region corresponds to a region where patterns of the isolation films are located, and the third photoresist unreserved region corresponds to the other region, and the black frame is a frame surrounding a display region of the touch panel;
etching the black frame material layer and the transparent insulating material layer in the third photoresist unreserved region;
ashing the third photoresist in the third photoresist partially-reserved region;
etching the black frame material layer in the third photoresist partially-reserved region and forming the patterns of the isolation films which are only generated from the transparent insulating material layer; wherein the signal lines overlap the black frame in a light-transmitting direction of the display region, and the plurality of connection bridges are surrounded by the black frame; and
removing the remaining third photoresist.

7. The method according to claim 1, wherein each isolation film covers a middle portion of one corresponding connection bridge.

8. The method according to claim 1, wherein each connection bridge extends along a column direction, the plurality of first sub-electrodes of each first touch electrode extends along the column direction and is bridged through a corresponding column of connection bridges; each isolation film extends along a row direction, each second touch electrode extends along the row direction and comprises a plurality of second sub-electrodes, and connecting portions between adjacent second sub-electrodes are located on a corresponding row of isolation films.

9. The method according to claim 8, wherein the number of columns of the plurality of connection bridges is equal to the number of the plurality of first touch electrodes, the number of rows of the plurality of connection bridges is less than the number of the first sub-electrodes of each first touch electrode by 1; and the number of rows of the plurality of isolation films is equal to the number of the plurality of second touch electrodes, and the number of columns of the plurality of isolation films is less than the number of the second sub-electrodes of each second touch electrode by 1.

10. A touch panel, comprising:
a substrate;
signal lines and a plurality of connection bridges formed on the substrate, the plurality of connection bridges being disposed in the form of a matrix;
a plurality of isolation films arranged in one-to-one correspondence with the plurality of connection bridges, wherein each isolation film covers at least a portion of one corresponding connection bridge; and
a plurality of first touch electrodes and a plurality of second touch electrodes which are made of nano-silver; wherein the plurality of first touch electrodes and the plurality of second touch electrodes are connected to the signal lines, each of the plurality of first touch electrodes comprises a plurality of first sub-electrodes, any two adjacent first sub-electrodes among the plurality of first sub-electrodes are bridged through one corresponding connection bridge, and the plurality of second touch electrodes is insulated from the plurality of connection bridges through the plurality of isolation films.

11. The touch panel according to claim 10, further comprising:
a black frame, wherein the black frame is a frame surrounding a display region of the touch panel, and the black frame is disposed between the substrate and the signal lines or disposed at an identical layer to the plurality of isolation films;
wherein the signal lines at least partially overlap the black frame.

12. The touch panel according to claim 10, wherein each isolation film covers a middle portion of one corresponding connection bridge.

13. The touch panel according to claim 10, wherein each connection bridge extends along a column direction, the plurality of first sub-electrodes of each first touch electrode extends along the column direction and is bridged through a corresponding column of connection bridges; each isolation film extends along a row direction, each second touch electrode extends along the row direction and comprises a plurality of second sub-electrodes, and connecting portions between adjacent second sub-electrodes are located on a corresponding row of isolation films.

14. The touch panel according to claim 13, wherein the number of columns of the plurality of connection bridges is equal to the number of the plurality of first touch electrodes, the number of rows of the plurality of connection bridges is less than the number of the first sub-electrodes of each first touch electrode by 1; and the number of rows of the plurality of isolation films is equal to the number of the plurality of second touch electrodes, and the number of columns of the plurality of isolation films is less than the number of the second sub-electrodes of each second touch electrode by 1.

15. A touch display device, comprising a touch panel, wherein the touch panel comprises:
a substrate;
signal lines and a plurality of connection bridges formed on the substrate, the plurality of connection bridges being disposed in the form of a matrix;
a plurality of isolation films arranged in one-to-one correspondence with the plurality of connection bridges, wherein each isolation film covers at least a portion of one corresponding connection bridge; and
a plurality of first touch electrodes and a plurality of second touch electrodes which are made of nano-silver; wherein the plurality of first touch electrodes and the plurality of second touch electrodes are connected to the signal lines, each of the plurality of first touch electrodes comprises a plurality of first sub-electrodes, any two adjacent first sub-electrodes among the plurality of first sub-electrodes are bridged through one corresponding connection bridge, and the plurality of second touch electrodes is insulated from the plurality of connection bridges through the plurality of isolation films.

16. The touch display device according to claim 15, wherein the touch panel further comprises:
a black frame, wherein the black frame is a frame surrounding a display region of the touch panel, and the black frame is disposed between the substrate and the signal lines or disposed at an identical layer to the plurality of isolation films;
wherein the signal lines at least partially overlap the black frame.

17. The touch display device according to claim 15, wherein each isolation film covers a middle portion of one corresponding connection bridge.

18. The touch display device according to claim 15, wherein each connection bridge extends along a column direction, the plurality of first sub-electrodes of each first touch electrode extends along the column direction and is bridged through a corresponding column of connection bridges; each isolation film extends along a row direction, each second touch electrode extends along the row direction and comprises a plurality of second sub-electrodes, and connecting portions between adjacent second sub-electrodes are located on a corresponding row of isolation films.

19. The touch display device according to claim 18, wherein the number of columns of the plurality of connection bridges is equal to the number of the plurality of first touch electrodes, the number of rows of the plurality of connection bridges is less than the number of the first sub-electrodes of each first touch electrode by 1; and the number of rows of the plurality of isolation films is equal to the number of the plurality of second touch electrodes, and the number of columns of the plurality of isolation films is less than the number of the second sub-electrodes of each second touch electrode by 1.
